(19) United States
(12) Patent Application Publication
(10) Pub. No.: US 2010/0116436 A1
(43) Pub. Date: May 13, 2010

(54) RING-SHAPED MEMBER AND METHOD FOR MANUFACTURING SAME

(75) Inventors: Tsuguo KITAJIMA, Nirasaki City (JP); Yoshiyuki Kobayashi, Nirasaki City (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: TOKYO ELECTRON LIMITED, Tokyo (JP)

(21) Appl. No.: 12/613,043

(22) Filed: Nov. 5, 2009

Related U.S. Application Data
(60) Provisional application No. 61/163,480, filed on Mar. 26, 2009.

(30) Foreign Application Priority Data
Nov. 7, 2008 (JP) 2008-286686

(51) Int. Cl. C23F 1/00; B23K 10/00; B23P 11/00; C23C 16/00

(52) U.S. Cl. 156/345.1; 219/121.48; 29/428; 118/723 R; 156/915

(57) ABSTRACT

A ring-shaped member is used in a chamber of a substrate processing apparatus for performing a plasma processing on a substrate by generating a plasma in the chamber. The ring-shaped member includes a plurality of circular arc-shaped members made of single crystalline material and arranged along a circumferential direction of the ring-shaped member. Each of the circular arc-shaped members includes a surface exposed to the plasma when the plasma is generated in the chamber and an easily erodible crystal plane of the single crystalline material is not exposed at the surface.

### CROSS-REFERENCE TO RELATED APPLICATIONS

This application claims priority to Japanese Patent Application No. 2008-286686 filed on Nov. 7, 2008, the entire contents of which are incorporated herein by reference.

### FIELD OF THE INVENTION

The present invention relates to a ring-shaped member and a method for manufacturing the same; and, more particularly, to a ring-shaped member having a surface exposed to a plasma.

### BACKGROUND OF THE INVENTION

In a substrate processing apparatus for performing a predetermined plasma processing on a disc-shaped semiconductor wafer, ring-shaped members shaped in harmony with the disc-shaped wafer are arranged in an accommodation chamber wherein the wafer is accommodated and a plasma is generated.

A focus ring is known as a typical example of the ring-shaped member. The focus ring is a ring-shaped member surrounding a periphery of the wafer, and is conventionally made of a dielectric material. Thus, the focus ring serves to confine the plasma generated in the accommodation chamber in a space above the wafer, thus facilitating the plasma processing.

With a recent trend towards a large diameter of a wafer, the uniformity of the plasma processing throughout the whole area of the wafer becomes more important than the facilitation of the plasma processing. In case that the focus ring is made of a dielectric material as described above, the plasma may concentrate along the boundary between the wafer and the focus ring and, thus, the uniformity of the plasma processing cannot be achieved in the peripheral portion of the wafer. Therefore, there is provided a focus ring which is partially or entirely made of an electrical conductor so that a plasma distribution region is extended from the space above the wafer to a space above the focus ring to maintain the uniformity of the plasma processing (see, e.g., Japanese Patent Application Publication No. 2002-246370 and its corresponding U.S. Patent Application Publication No. 20040074605).

In view of maintaining the uniformity of the plasma processing, a single crystalline silicon same as the material of the wafer is preferably used as the electrical conductor forming the focus ring. Moreover, a single crystalline silicon ingot is used in a method for manufacturing a focus ring same as in a method for manufacturing a wafer.

FIGS. 8A to 8D present a processing sequence describing a general method for manufacturing a focus ring.

First, a single crystalline silicon ingot is shaped as a solid cylindrical member 80 having a predetermined diameter (FIG. 8A), and a plurality of circular plates 81 is obtained by slicing the solid cylindrical member 80 (FIG. 8B). Next, a peripheral portion of each circular plate 81 is cut to form a focus ring 82 (FIGS. 8C and 8D).

In that case, however, a circular plate 83 remains as a leftover from the cutting operation in which the focus ring 82 is cut from the circular plate 81. The diameter of the circular plate 83 is smaller than that of the focus ring 82, so that the peripheral portion of the circular plate 83 cannot be cut to from the focus ring 82. This deteriorates the productivity for the manufacture of the focus ring 82.

Further, when the focus ring 82 is cut as a single unit from the circular plate 81 made of single crystalline silicon, the degree of freedom of the cutting position is low. Therefore, an easily erodible crystal plane of single crystalline silicon may appear on the surface of the focus ring 82 to be exposed to the plasma. As a result, the consumption of the focus ring 82 by the plasma increases.

### SUMMARY OF THE INVENTION

In view of the above, the present invention provides a ring-shaped member that reduces its erosion by a plasma and its productivity deterioration and a method for manufacturing the same.

In accordance with an aspect of the present invention, there is provided a ring-shaped member for use in a chamber of a substrate processing apparatus for performing a plasma processing on a substrate by generating a plasma in the chamber, the ring-shaped member including: a plurality of circular arc-shaped members made of single crystalline material and arranged along a circumferential direction of the ring-shaped member, wherein each of the circular arc-shaped members includes a surface exposed to the plasma when the plasma is generated in the chamber and an easily erodible crystal plane of the single crystalline material is not exposed at the surface.

In accordance with another aspect of the present invention, there is provided a method for manufacturing a ring-shaped member accommodated in a chamber of a substrate processing apparatus for performing a plasma processing on a substrate by generating a plasma in the chamber, the method including: fabricating a plurality of first ring-shaped members from a peripheral portion of a cylindrical member, which is made of a single crystalline material and has a predetermined diameter; cutting a plurality of circular arc-shaped members having a curvature identical to that of the first ring-shaped member from a member remaining as a leftover from the fabricating operation in which the first ring-shaped member is cut from the cylindrical member; and

arranging the circular arc-shaped members along a circumferential direction and bonding the arranged members one another to form a second ring-shaped member, wherein each of the circular arc-shaped members includes a surface exposed to the plasma when the plasma is generated in the chamber and an easily erodible crystal plane of the single crystalline material is not exposed at the surface in said cutting the plurality of circular arc-shaped members.

### BRIEF DESCRIPTION OF THE DRAWINGS

The objects and features of the present invention will become apparent from the following description of embodiments, given in conjunction with the accompanying drawings, in which:

FIG. 1 is a cross sectional view schematically showing a configuration of a substrate processing apparatus including a focus ring as a ring-shaped member in accordance with an embodiment of the present invention;

FIG. 2 depicts a perspective view for explaining a detailed configuration of the focus ring shown in FIG. 1;

FIGS. 3A to 3C provide a processing sequence presenting a method of manufacturing a focus ring as an example of manufacturing a ring-shaped member in accordance with the embodiment of the present invention;

FIGS. 4A to 4F present a processing sequence showing a modification of the method of manufacturing a focus ring as the example of manufacturing a ring-shaped member in accordance with the embodiment of the present invention;

FIGS. 5A and 5B schematically show a modification of a configuration around an electrostatic chuck and the focus ring in the substrate processing apparatus shown in FIG. 1, wherein FIG. 5A is a cross sectional view and FIG. 5B is a top view;

FIG. 6 presents a cross sectional view schematically illustrating a configuration of a substrate processing apparatus including a ground electrode as a ring-shaped member in accordance with an embodiment of the present invention;

FIG. 7 represents a cross sectional view schematically describing a configuration of a substrate processing apparatus including an outer electrode plate as a ring-shaped member in accordance with an embodiment of the present invention; and

FIGS. 8A to 8D set forth a processing sequence showing a general method for manufacturing a focus ring.

### DETAILED DESCRIPTION OF EMBODIMENTS

Hereinafter, embodiments of the present invention will be described with reference to the accompanying drawings which form a part hereof.

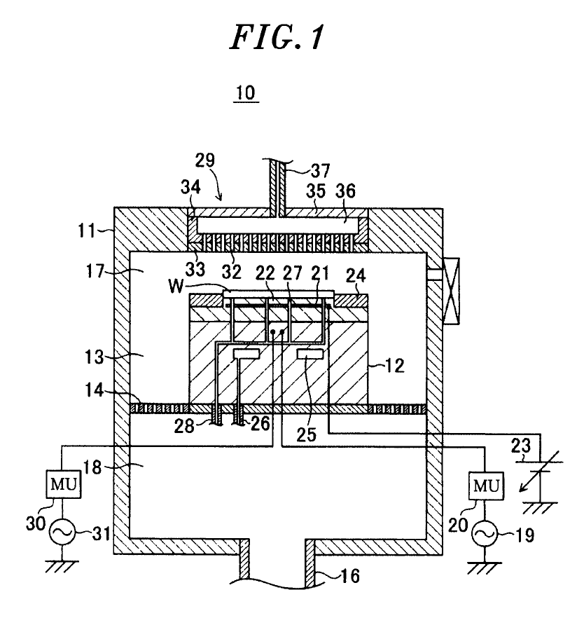

FIG. 1 is a cross sectional view schematically showing a configuration of a substrate processing apparatus including a focus ring serving as a ring-shaped member in accordance with an embodiment. The substrate processing apparatus is configured to perform a plasma etching process on a wafer.

Referring to FIG. 1, a substrate processing apparatus includes a chamber 11 (accommodation chamber) that accommodates therein a wafer W, which is made of, e.g., single crystalline silicon and has a diameter of about 300 mm, and a cylindrical susceptor 12 on which the wafer W is mounted is disposed in the chamber 11. Further, in the substrate processing apparatus 10, a side exhaust passageway serving as a passageway for exhausting a gas present above the susceptor 12 to the outside of the chamber 11 is formed by an inner sidewall of the chamber 11 and a side surface of the susceptor 12. A gas exhaust plate 14 is provided in the middle of the side exhaust passageway 13.

The gas exhaust plate 14 is a plate-shaped member having a plurality of openings, and serves as a partition plate for partitioning the chamber 11 into an upper space and a lower space. A plasma is generated in the upper space (hereinafter, referred to as a “reaction chamber”) 17 of the chamber 11 partitioned by the exhaust plate 14. Further, a gas exhaust pipe 16 for exhausting the gas in the chamber 11 is connected to the lower space (hereinafter, referred to as “exhaust chamber (manifold)”) 18 of the chamber 11. The gas exhaust plate 14 traps or reflects the plasma generated in the reaction chamber 17 and hence prevents the plasma from leaking into the manifold 18.

The gas exhaust pipe 16 is connected to a TMP (Turbo Molecular Pump) and a DP (Dry Pump) (both not shown) which evacuate and depressurize the chamber 11. Specifically, the DP depressurizes the chamber 11 from the atmospheric pressure to a medium vacuum state (e.g., 1.3×10 Pa (0.1 Torr) or lower), and the TMP cooperates with the DP to depressurize the chamber 11 to a high vacuum state, the pressure in which is lower than that in the medium vacuum state, (e.g., 1.3×10⁻³ Pa (1.0×10⁻⁵ Torr) or lower). Further, the pressure in the chamber 11 is controlled by an APC valve (not shown).

The susceptor 12 in the chamber 11 is connected to a first high frequency power supply 19 via a first matching unit (MU) 20, and is also connected to a second high frequency power supply 31 via a second matching unit (MU) 30. The first high frequency power supply 19 supplies to the susceptor 12 a high frequency power of a relatively low frequency for ion attraction, and the second high frequency power supply 31 supplies to the susceptor 12 a high frequency power of a relatively high frequency for plasma generation. The susceptor 12 therefore functions as an electrode. Further, the first and the second matching unit 20 and 30 reduce reflections of the high frequency powers from the susceptor 12 to maximize the efficiency in supplying the high-frequency powers to the susceptor 12.

An electrostatic chuck 22 having therein an electrostatic electrode plate 21 is disposed on an upper portion of the susceptor 12. The electrostatic chuck 22 is configured to include a lower disc-shaped member having a certain diameter and an upper disc-shaped member mounted thereon and having a diameter smaller than that of the lower disc-shaped member. Further, the lower and the upper disc-shaped member are made of a ceramic material. When the wafer W is mounted on the susceptor 12, the wafer W is mounted on the upper disc-shaped member of the electrostatic chuck 22.

A DC power supply 23 is electrically connected to the electrostatic electrode plate 21 in the electrostatic chuck 22. When a positive DC voltage is applied to the electrostatic electrode plate 21, a negative potential is produced on the surface of the wafer W that faces the electrostatic chuck 22 (hereinafter referred to as a “backside”). A potential difference is thus generated between the electrostatic electrode plate 21 and the backside of the wafer W, and the wafer W is attracted to be held on the upper disc-shaped member of the electrostatic chuck 22 due to a coulomb force or a Johnsen-Rahbek force resulting from the potential difference.

Further, a ring-shaped member serving as a focus ring is directly disposed on the electrostatic chuck 22 to surround the wafer W attracted and held on the electrostatic chuck 22. The focus ring 24 is made of an electrically conductive material, e.g., single crystalline silicon same as that forming the wafer W. Since the focus ring 24 is made of the electrical conductor, the plasma is distributed throughout a space above the wafer W and the focus ring 24 and the plasma density on the peripheral portion of the wafer W is made to be maintained at a level substantially equal to that on the central portion of the wafer W. Accordingly, the uniformity of the plasma etching processing on the entire of the wafer W can be maintained.

An annular coolant chamber 25 extending in, e.g., a circumferential direction of the susceptor 12, is provided in the susceptor 12. A low-temperature coolant, such as cooling water or Galden (registered trademark), is supplied from a chiller unit (not shown) to the coolant chamber 25 through a coolant line 26 to be circulated in the coolant chamber 25. The susceptor 12 cooled by the low-temperature coolant cools the wafer W and the focus ring 24 via the electrostatic chuck 22.

A plurality of heat-transfer gas supply holes 27 are formed in the portion of the upper disc-shaped member of the electrostatic chuck 22 where the wafer W is attracted and held (hereinafter referred to as an “attracting surface”). The heat-transfer gas supply holes 27 are connected to a heat-transfer gas supply unit (not shown) through a heat-transfer gas supply line 28, and the heat-transfer gas supply unit supplies, e.g., helium (He) gas as a heat-transfer gas to a gap between the attracting surface and the backside of the wafer W through the heat-transfer gas supply holes 27. The He gas supplied to the gap described above effectively transfers heat from the wafer W to the electrostatic chuck 22.

A shower head 29 is disposed at the ceiling of the chamber 11 to oppositely face the susceptor 12. The shower head 29 includes a disc-shaped ceiling electrode plate 33 having a plurality of gas holes 32, a cooling plate 34 from which the ceiling electrode plate 33 is detachably suspended, and a cover 35 that covers the cooling plate 34. Further, a buffer chamber 36 is provided inside the cooling plate 34, and a processing gas inlet line 37 is connected to the buffer chamber 36. In the shower head 29, a processing gas supplied into the buffer chamber 36 through the processing gas inlet line 37 is supplied into the reaction chamber 17 through the gas holes 32.

The operation of the components of the above-described substrate processing apparatus 10 is controlled by a CPU in a control unit (not shown) of the substrate processing apparatus 10 in accordance with a program for the plasma etching process.

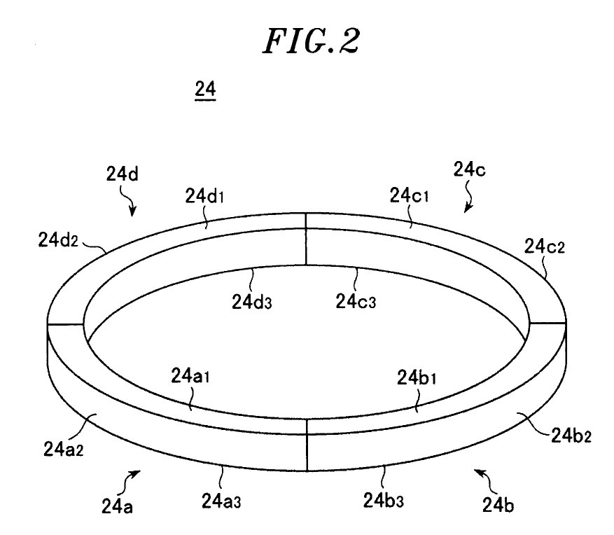

FIG. 2 is a perspective view for explaining a detailed configuration of the focus ring shown in FIG. 1.

Referring to FIG. 2, the focus ring 24 is formed by, e.g., four circular arc-shaped members 24a to 24d having a same curvature. Preferably, the circular arc-shaped members 24a to 24d are arranged along a circumferential direction, and neighboring circular arc-shaped members are thermally bonded to each other through fusion bonding or diffusion bonding. Moreover, the thermally bonded portions between the circular arc-shaped members 24a to 24d are preferably amorphized, i.e., become an amorphous material.

The circular arc-shaped members 24a to 24d of the focus ring 24 respectively include top surfaces 24a₁ to 24d₁ that are parallel to the surface of the wafer W, which is mounted on the attracting surface of the electrostatic chuck 22 when the focus ring 24 is mounted on the electrostatic chuck 22; outer surfaces 24a₂ to 24d₂ perpendicularly adjoining to the top surfaces 24a₁ to 24d₁; and bottom surfaces 24a₃ to 24d₃ that are disposed opposite to the top surfaces 24a₁ to 24d₁; and come into contact with the electrostatic chuck 22 when the focus ring 24 is mounted on the electrostatic chuck 22.

The top surfaces 24a₁ to 24d₁ and the outer surfaces 24a₂ to 24d₂ of the focus ring 24 are exposed to the inside of the reaction chamber 17 and, therefore, are exposed to the plasma when the plasma is generated from the processing gas in the reaction chamber 17. Especially, when the plasma etching process is performed on the wafer W, the high frequency power for ion attraction is applied to the susceptor 12. Accordingly, ions in the plasma are attracted to the top surfaces 24a₁ to 24d₁ of the focus ring 24 as well as to the surface of the wafer W, so that the top surfaces 24a₁ to 24d₁ of the focus ring 24 are sputtered. When the focus ring 24 is eroded by the sputtering, the plasma distribution above the focus ring 24 is disturbed, thereby making it difficult to maintain the uniformity of the plasma etching process on the wafer W.

Thus, in the present embodiment, easily erodible crystal planes of single crystalline silicon, e.g., a family of low-index crystal planes, such as (100), (010) or (001) plane which is denoted by Miller index {100} are prevented from appearing on the top surfaces 24a₁ to 24d₁ and the outer surfaces 24a₂ to 24d₂ exposed to the plasma. Specifically, the circular arc-shaped members 24a to 24d are cut from a bulk material of single crystalline silicon in such a way that the easily erodible crystal planes of single crystalline silicon are prevented from appearing on the top surfaces 24a₁ to 24d₁ and the outer surfaces 24a₂ to 24d₂.

Further, when the focus ring 24 is made of a material other than single crystalline silicon, e.g., a material of a hexagonal lattice system, e.g., SiC, low-index crystal planes which are denoted by Miller indices of four-index notation (Bravais-Miller indices) indicated by the following expression (1) and, more specifically, e.g., the following expression (2) are prevented from being exposed on the top surfaces 24a₁ to 24d₁ and the outer surfaces 24a₂ to 24d₂:

(1010), {01 1̅0} (1), and

(10 1̅0), (01 1̅0), ( 1̅100), ( 1̅010), (0 1̅10) or (1 1̅00) (2).

In the focus ring 24, the crystal planes exposed on the bottom surfaces 24a₃ to 24d₃ that are not exposed to the plasma may be denoted by the aforementioned Miller indices of low-index notation, whereas the crystal planes exposed on the top surfaces 24a₁ to 24d₁ and the outer surfaces 24a₂ to 24d₂ are denoted by Miller indices, e.g., (211), (118) and (131), or those of four-index notation indicated by the following expression (3):

(20 2̅1), (3 3̅02), ( 1̅108) (3).

Further, in the focus ring 24, the crystal planes exposed on the top surfaces 24a₁ to 24d₁ of the circular arc-shaped members 24a to 24d are preferably denoted by Miller indices of the same index notation. However, when the crystal planes are denoted by Miller indices of high-index notation, the crystal planes may be denoted by Miller indices of different index notation.

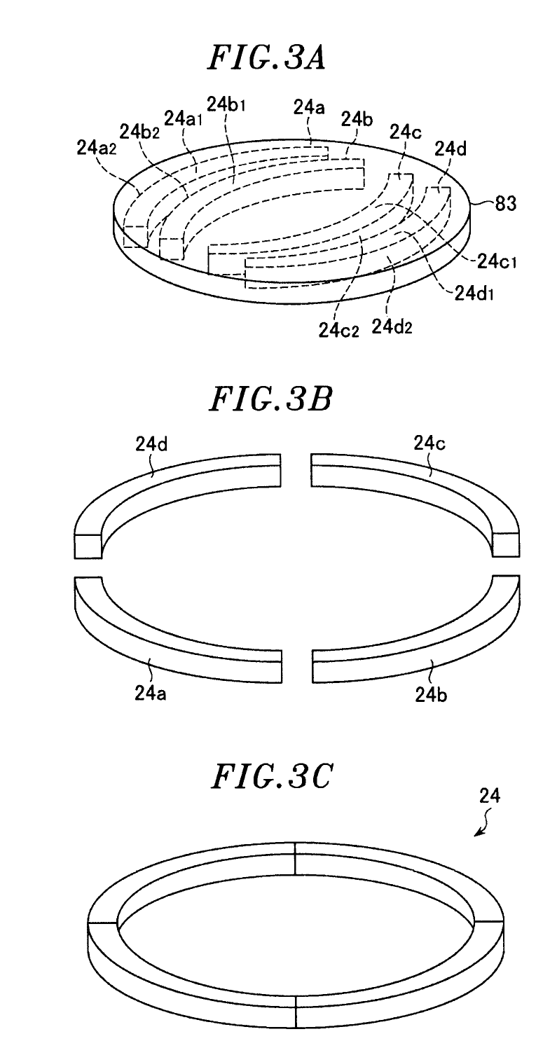

FIGS. 3A to 3C provide a processing sequence showing a method for manufacturing a focus ring serving as a ring-shaped member in accordance with the present embodiment.

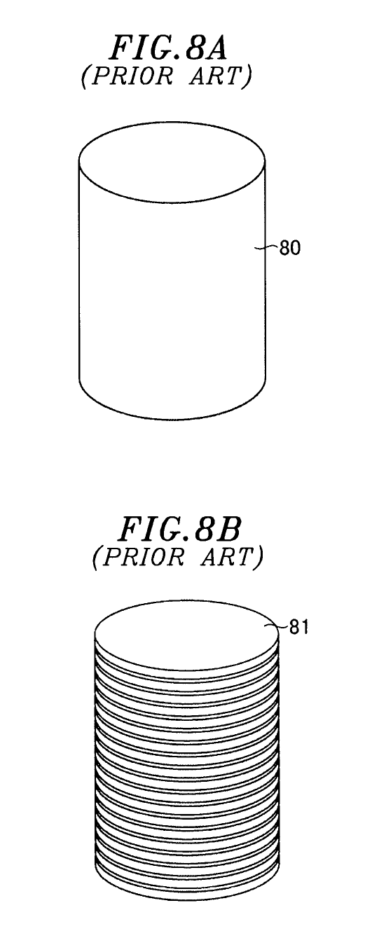

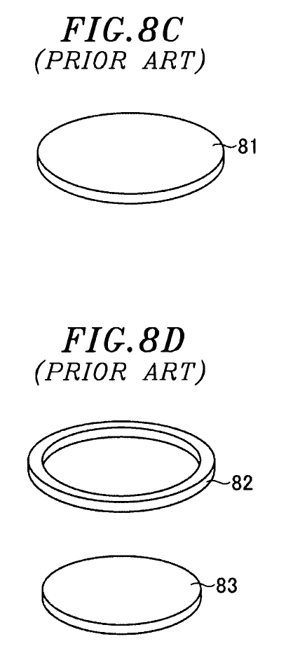

First, as shown in FIGS. 8A to 8D, the circular plates 81 are sliced from the solid cylindrical member 80, which is made of single crystalline silicon and has a predetermined diameter. The peripheral portion of each of the circular plates 81 is cut to obtain a focus ring 82 as a single unit (first ring-shaped member) (first cutting step). Next, by cutting the circular plate 83 that is a leftover from the cutting operation in which the focus ring 82 is cut from the circular plate 81, a plurality of circular arc-shaped members 24a to 24d having a curvature same as that of the focus ring 82 can be produced (second cutting step) (FIG. 3A). In that case, the circular arc-shaped members 24a to 24d are cut in such a way that an easily erodible crystal plane of single crystalline silicon is not exposed on the top surfaces 24a₁ to 24d₁ and the outer surfaces 24a₂ to 24d₂ of the circular arc-shaped members 24a to 24d, that is, the top surfaces 24a₁ to 24d₁ of the circular arc-shaped members 24a to 24d for example is not the easily erodible crystal plane.

Next, the circular arc-shaped members 24a to 24d are arranged along the circumferential direction (FIG. 3B). The neighboring circular arc-shaped members are thermally bonded to one another by, e.g., diffusion bonding, thereby forming a focus ring 24 (second ring-shaped member) (FIG. 3C) (bonding step).

A ring-shaped member serving as the focus ring 24 in accordance with an embodiment of the present invention can be made of the circular arc-shaped members 24a to 24d arranged along a circumferential direction. In other words, the focus ring 24 can be manufactured by using the circular arc-shaped members 24a to 24d obtained by cutting the circular plate 83, which is a member remaining as a leftover from the cutting operation in which the focus ring 82 is cut from the solid cylindrical member 80. Accordingly, the productivity for the manufacture of the focus ring 24 can be improved.

During the plasma etching process, the ions in the plasma are attracted to the surface of the wafer W and also the top surfaces 24a₁ to 24d₁ parallel to the surface of the wafer W. Since, however, each of the circular arc-shaped members 24a to 24d can be cut from various portions of the circular plate 83, the circular arc-shaped members 24a to 24d can be cut without exposing an easily erodible crystal plane of single crystalline silicon, e.g., a low-index crystal plane, e.g., {100} on the top surfaces 24a₁ to 24d₁ and the outer surfaces 24a₂ to 24d₂ of the circular arc-shaped members 24a to 24d. Accordingly, the erosion of the focus ring 24, which is caused by the plasma, can be suppressed. As a result, the uniform distribution of the plasma on the peripheral portion of the wafer W can be prevented from being disturbed, and the uniformity of the plasma processing on the wafer W can be maintained for a long period of time.

In the above-described embodiment, the circular arc-shaped members 24a to 24d are cut from the circular plate 83. However, the circular arc-shaped members 24a to 24d can be directly cut from the solid cylindrical member 80. In that case, the circular arc-shaped members 24a to 24d are also cut in such a way that an easily erodible crystal plane of single crystalline silicon is not exposed on the top surfaces 24a₁ to 24d₁ and the outer surfaces 24a₂ to 24d₂ of the circular arc-shaped members 24a to 24d.

In the above-described focus ring 24, the single crystalline silicon forming the focus ring 24 is the same as the single crystalline silicon forming the wafer W. Therefore, the plasma distribution region is extended from a space above the wafer W to a space also including an additional area above the focus ring 24 and, hence, the plasma density on the peripheral portion of the wafer can be maintained at a level substantially equal to on the central portion of the wafer W. Accordingly, the uniformity of the plasma processing can be maintained on the peripheral portion of the wafer near the focus ring 24.

Moreover, in the above-described focus ring 24, when the circular arc-shaped members 24a to 24d are arranged such that the crystal planes denoted by the same Miller indices are exposed on the top surfaces 24a₁ to 24d₁ of the circular arc-shaped members 24a to 24d, the top surfaces 24a₁ to 24d₁ can be uniformly eroded by the plasma etching process and, further, the uniform distribution of the plasma above the top surfaces 24a₁ to 24d₁ can be prevented from being disturbed.

Furthermore, in the above-described focus ring 24, the circular arc-shaped members 24a to 24d are thermally bonded to each other, and the thermally bonded portions therebetween are amorphized. Therefore, crystal lattices between neighboring circular arc-shaped members can be continuously connected without grain interfaces or lattice defects. Accordingly, the strength of the focus ring 24 can be further increased, thereby facilitating the handling of the focus ring 24. In addition, the thermally bonded portions are homogenized by amorphization, so that the uniform distribution of the plasma in area above the ring-shaped member can be prevented from being disturbed when the ring-shaped member is electrically charged.

In the aforementioned focus ring 24, the circular arc-shaped members 24a to 24d are thermally bonded to one another. However, they may be adhered to one another by an adhesive agent. Therefore, the focus ring 24 can be easily formed and, further, the productivity for the manufacture of the focus ring 24 can be further improved.

Further, the manufacturing method of the focus ring 24 is not limited to the manufacturing method described in FIGS. 3A to 3C.

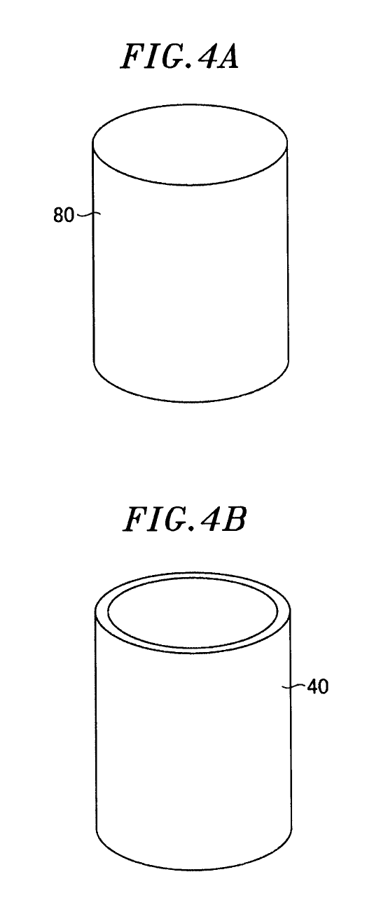

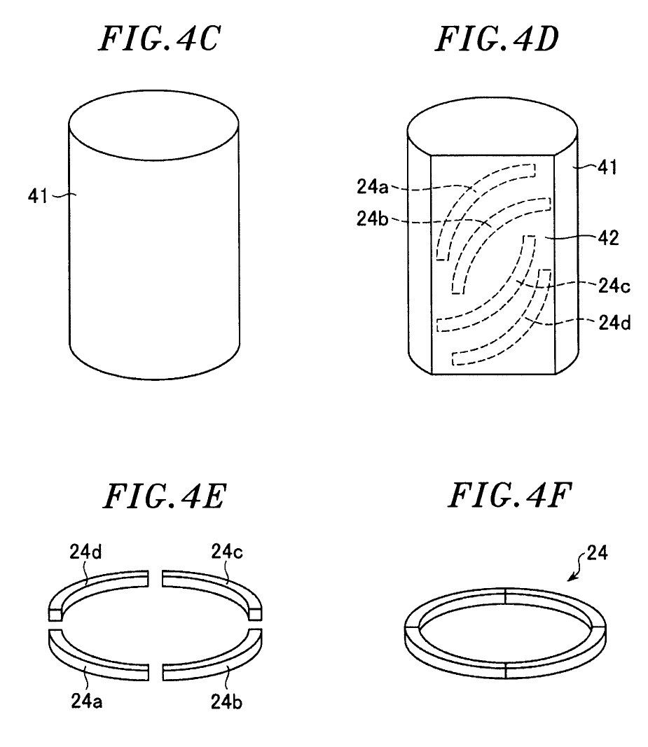

FIGS. 4A to 4F offer a processing sequence illustrating a modification of the method for manufacturing a focus ring as a method for manufacturing a ring-shaped member in accordance with another embodiment.

First, the peripheral portion of the solid cylindrical member 80, which is made of single crystalline silicon and has a predetermined diameter, is cut to form a ring-shaped wall member (hollow cylindrical member) (FIG. 4A), and the focus ring 82 (first ring-shaped member) is sliced as a single unit from the ring-shaped wall member 40 thus obtained (FIG. 4B) (first cutting step).

Next, as a result of the cutting operation in which the ring-shaped wall member 40 is cut from the solid cylindrical member 80, a solid cylindrical member 41 (FIG. 4C) remains to be a leftover therefrom. A side portion of the solid cylindrical member 41 is cut to have a flat surface 42 on the side surface of the solid cylindrical member 41. A plurality of circular arc-shaped members 24a to 24d having a curvature same as that of the focus ring 82 is obtained by cutting the flat surface 42 (FIG. 4D) (second cutting step). In that case, as in the manufacturing method described in FIGS. 3A to 3C, the circular arc-shaped members 24a to 24d are cut in such a way that an easily erodible crystal plane of single crystalline silicon is not exposed on the top surfaces 24a₁ to 24d₁ and the outer surfaces 24a₂ to 24d₂ of the circular arc-shaped members 24a to 24d.

Thereafter, the circular arc-shaped members 24a to 24d are arranged along the circumferential direction (FIG. 4E), and the neighboring circular arc-shaped members are thermally bonded to each other by diffusion bonding, thereby forming the focus ring 24 (second ring-shaped member) (FIG. 4F) (bonding step).

Meanwhile, the trend towards a large diameter of the wafer W is likely to continue, and the wafer W having a diameter of about 450 mm is expected to be a mainstream in the near future. In that case, in order to manufacture the focus ring 82 as a single unit, there is required a cylindrical member (ingot) made of single crystalline silicon and having a diameter greater than or equal to about 500 mm. However, it is difficult to manufacture an ingot having such diameter.

In the manufacturing method shown in FIGS. 4A to 4F, circular arc-shaped members 24a to 24d having a radius of curvature greater than that of the cylindrical ingot (solid cylindrical member 41) can be produced so that the focus ring 24 having a diameter greater than that of the ingot can be manufactured by cutting the ingot. Therefore, it is possible to deal with the trend towards a large diameter of the wafer W.

In the above substrate processing apparatus 10, the focus ring 24 is directly mounted on the electrostatic chuck 22. However, if the focus ring 24 is not firmly adhered to the electrostatic chuck 22, a vacuum layer having a low thermal conductivity is formed between the focus ring 24 and the electrostatic chuck 22, so that the focus ring 24 heated by impinging ions thereto cannot be effectively cooled by the electrostatic chuck 22 during the plasma etching process. In that case, the temperature of the focus ring 24 increases to about 500° C. and, thus, the peripheral portion of the wafer W is heated by radiant heat from the focus ring 24, which makes it difficult to maintain the uniformity of the plasma etching process on the wafer W.

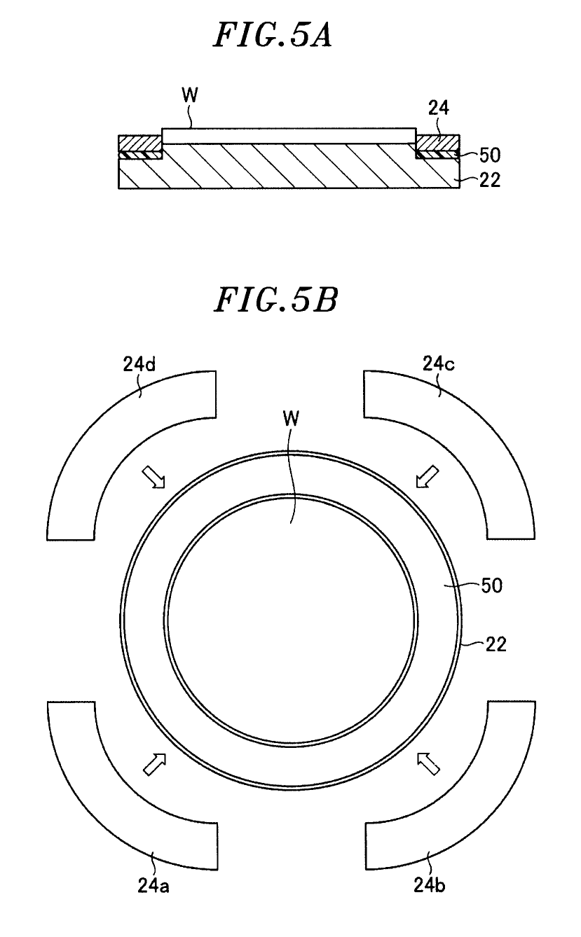

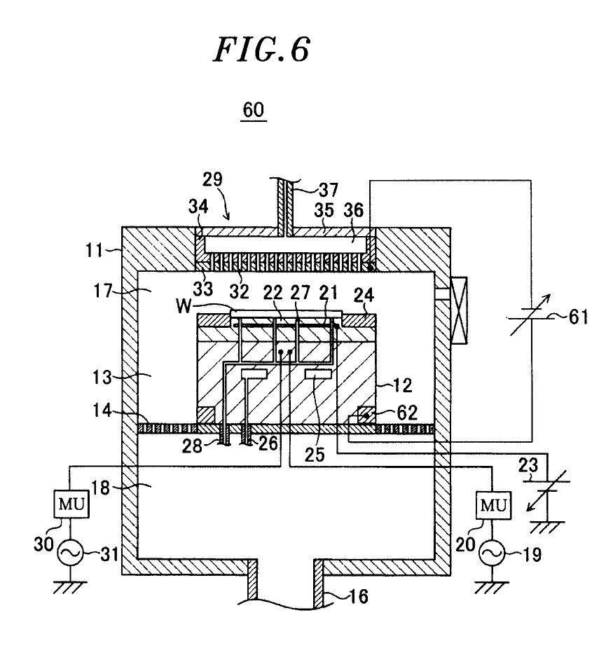

Therefore, as illustrated in FIG. 5A, the adhesivity between the focus ring 24 and the electrostatic chuck 22 can be improved by inserting a heat transfer sheet 50 between the electrostatic chuck 22 and the focus ring 24. Accordingly, the formation of the vacuum layer between the focus ring 24 and the electrostatic chuck 22 can be prevented, and the focus ring 24 can be effectively cooled through the electrostatic chuck 22.

When a ring-shaped resin sheet having adhesivity is used as the heat transfer sheet 50, the ring-shaped heat transfer sheet 50 is disposed first on the electrostatic chuck 22, and the circular arc-shaped members 24a to 24d are arranged along the circumferential direction while adhering to the heat transfer sheet 50. Accordingly, the circular arc-shaped members 24a to 24d form the focus ring 24 on the electrostatic chuck 22 without bonding each other. As a result, the productivity for the manufacture of the focus ring 24 can be further improved.

The ring-shaped member in accordance with the present embodiment can be applied to components of the substrate processing apparatus other than the aforementioned focus ring 24. For example, in order to improve the performance of the plasma processing, there is developed a substrate processing apparatus 60 in which a DC voltage is applied from a DC power supply 61 connected to a ceiling electrode plate 33 into a reaction chamber 17 as shown in FIG. 6. In order to apply a DC voltage into the reaction chamber 17, there is required a ground electrode 62 of a DC voltage, wherein a surface thereof is exposed to the inside of the reaction chamber 17.

The ground electrode 62 is a ring-shaped member made of an electrically conductive material, e.g., silicon, and disposed at a bottom portion of the suscepter 12 to surround therearound. The outer surface of the ground electrode 62 is facing the side exhaust passageway 13. Here, if the ground electrode 62 is formed by a plurality of circular arc-shaped members as in the case of the focus ring 24, the productivity for the manufacture of the ground electrode 62 can be improved. Further, when the circular arc-shaped members forming the ground electrode 62 are cut, they are cut such that an easily erodible crystal plane of single crystalline silicon is not exposed on the outer surface facing the side exhaust passageway 13. Accordingly, the erosion of the ground electrode 62, which is caused by the plasma, can be suppressed.

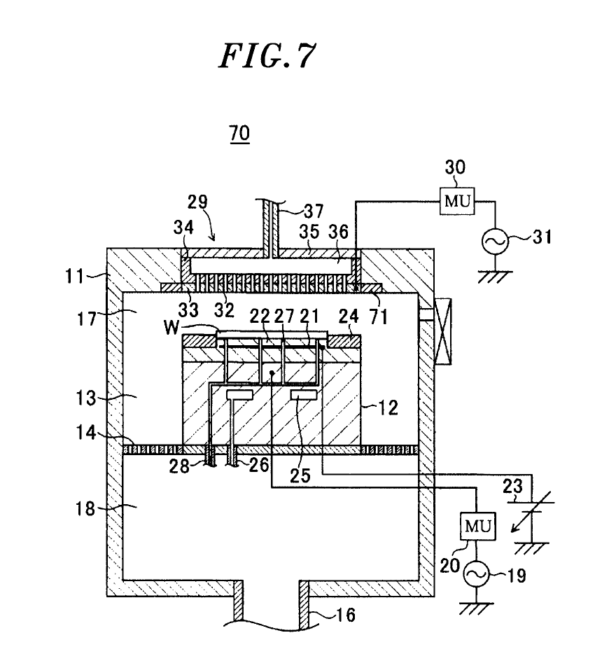

Further, there is conventionally known a substrate processing apparatus 70 in which the second high frequency power supply 31 is connected to the ceiling electrode plate instead of the susceptor 12 as shown in FIG. 7, and a high frequency power for plasma generation is supplied to the ceiling electrode plate 33 from the second high frequency power supply 31.

In this substrate processing apparatus 70, an outer electrode plate 71 (upper electrode) as a ring-shaped member made of an electric conductor, e.g., silicon, is disposed to surround the disc-shaped ceiling electrode plate 33. The outer electrode plate 71 has a bottom surface exposed to the inside of the reaction chamber 17.

Here, if the outer electrode plate 71 is formed by a plurality of circular arc-shaped members as in the case of the focus ring 24, the productivity for the manufacture of the outer electrode plate 71 can be improved. Moreover, when the circular arc-shaped members forming the outer electrode plate 71 are cut, they are cut such that an easily erodible crystal plane of single crystalline silicon does not surface on the bottom to be exposed to the inside of the reaction chamber 17. Accordingly, the erosion of the outer electrode plate 71, which is caused by the plasma, can be suppressed.

In the above-described embodiments, the substrate to which the plasma etching process is performed is a semiconductor wafer. However, the substrate to which the plasma etching process is performed is not limited thereto, and may be a glass substrate, e.g., an LCD (Liquid Crystal Display), an FPD (Flat Panel Display) or the like.

While the invention has been shown and described with respect to the embodiments, it will be understood by those skilled in the art that various changes and modification may be made without departing from the scope of the invention as defined in the following claims.

What is claimed is:

1. A ring-shaped member for use in a chamber of a substrate processing apparatus for performing a plasma processing on a substrate by generating a plasma in the chamber, the ring-shaped member comprising:
a plurality of circular arc-shaped members made of single crystalline material and arranged along a circumferential direction of the ring-shaped member,
wherein each of the circular arc-shaped members includes a surface exposed to the plasma when the plasma is generated in the chamber and an easily erodible crystal plane of the single crystalline material is not exposed at the surface.

2. The ring-shaped member of claim 1, wherein the easily erodible crystal plane is {100} plane.

3. The ring-shaped member of claim 1, wherein the easily erodible crystal plane is (0001) or {10 1̅0} plane.

4. The ring-shaped member of claim 1, wherein the circular arc-shaped members include surfaces exposed to the plasma, and a same crystal plane of the single crystalline material is exposed on the surfaces exposed to the plasma.

5. The ring-shaped member of claim 1, wherein the ring-shaped member surrounds a periphery of the substrate, and each of the circular arc-shaped members has a surface in parallel with a main surface of the substrate and a surface perpendicular to the main surface, and the easily erodible crystal plane of the single crystal material is not exposed on the main surface.

6. The ring-shaped member of claim 5, wherein the ring-shaped member is a focus ring.

7. The ring-shaped member of claim 5, wherein the ring-shaped member is an upper electrode of the substrate processing apparatus.

8. The ring-shaped member of claim 6, wherein the single crystalline material forming the focus ring is the same as a single crystalline material forming the substrate.

9. The ring-shaped member of claim 1, wherein the circular arc-shaped members are adhered to one another by an adhesive agent.

10. The ring-shaped member of claim 1, wherein the circular arc-shaped members are thermally bonded to one another.

11. The ring-shaped member of claim 10, wherein the thermally bonded portions of the circular arc-shaped members are amorphized.

12. A method for manufacturing a ring-shaped member accommodated in a chamber of a substrate processing apparatus for performing a plasma processing on a substrate by generating a plasma in the chamber, the method comprising:
fabricating a plurality of first ring-shaped members from a peripheral portion of a cylindrical member, which is made of a single crystalline material and has a predetermined diameter;
cutting a plurality of circular arc-shaped members having a curvature identical to that of the first ring-shaped member from a member remaining as a leftover from the fabricating operation in which the first ring-shaped member is cut from the cylindrical member; and
arranging the circular arc-shaped members along a circumferential direction and bonding the arranged members one another to form a second ring-shaped member,
wherein each of the circular arc-shaped members includes a surface exposed to the plasma when the plasma is generated in the chamber and an easily erodible crystal plane of the single crystalline material is not exposed at the surface in said cutting the plurality of circular arc-shaped members.

13. A substrate processing apparatus for performing a plasma processing on a substrate by generating a plasma in a chamber in which a ring-shaped member is accommodated, the ring-shaped member comprising:
a plurality of circular arc-shaped members made of single crystalline material and arranged along a circumferential direction of the ring-shaped member,
wherein each of the circular arc-shaped members includes a surface exposed to the plasma when the plasma is generated in the chamber and an easily erodible crystal plane of the single crystalline material is not exposed at the surface.
